(19) United States
(12) Patent Application Publication
(10) Pub. No.: US 2025/0076640 A1
(43) Pub. Date: Mar. 6, 2025

(54) OPTICAL AND MANUFACTURING AWARE DESIGN FLOW FOR METASURFACES

(71) Applicant: Synopsys, Inc., Sunnyvale, CA (US)

(72) Inventors: Maryvonne CHALONY, Puget sur Argens (FR); Lawrence S. MELVIN, III, Hillsboro, OR (US); Bernd KUECHLER, Radeberg (DE); Rainer ZIMMERMANN, Munich (DE); Ulrich KLOSTERMANN, Munich (DE); Emilie VIASNOFF, San Francisco, CA (US)

(21) Appl. No.: 18/821,920

(22) Filed: Aug. 30, 2024

Related U.S. Application Data
(60) Provisional application No. 63/579,930, filed on Aug. 31, 2023.

(51) Int. Cl. G02B 27/00

(52) U.S. Cl. CPC G02B 27/0012

(57) ABSTRACT

A method includes receiving a metasurface design including a plurality of meta-atoms arranged to modify phases of incident waves, the plurality of meta-atoms being from a library of different nominal meta-atoms; generating, by a processing device, a library of manufacturing-aware meta-atoms based on the library of different nominal meta-atoms; and generating instructions for fabricating a manufacturing-aware metasurface having layout computed using a cost function based on the metasurface design and the library of manufacturing-aware meta-atoms.

### RELATED APPLICATION

This application claims the benefit of U.S. Provisional Patent Application No. 63/579,930, filed in the United States Patent and Trademark Office on Aug. 31, 2023, the entire disclosure of which is incorporated by reference herein.

### TECHNICAL FIELD

The present disclosure relates to processes for optical element design for fabrication, in particular the design of electromagnetic metasurfaces for microfabrication.

### BACKGROUND

A metasurface such as an electromagnetic (e.g., optical) metasurface, a fluid metasurface, or an acoustic metasurface refers to a surface that is patterned with sub-resolution features, such as features smaller than the wavelength of the electromagnetic radiation or acoustic waves that the metasurface is designed to influence. As one example, a metalens includes quasi-periodic nanoscale features that affect the phase of incident light, where the nanoscale features of the metalens are designed to focus the light.

The above information disclosed in this Background section is only for enhancement of understanding of the present disclosure, and therefore it may contain information that does not form the prior art that is already known to a person of ordinary skill in the art.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1A is a schematic cross-sectional view of a nano-scale pillar or meta-atom formed on a silicon dioxide (SiO₂) or silicon substrate.

FIG. 1B is a schematic plan view of a nano-scale pillar or meta-atom, illustrating the pillar width (pw) parameter.

FIG. 1C is a graph depicting how transmission and phase vary with respect to the pillar width of the nano-scale pillar or meta-atom.

FIG. 2 is an example of a mask layout of a metalens designed according to one example embodiment of the present disclosure.

FIG. 3 provides examples of how the final geometries of the square meta-atom and plus meta-atom are impacted by a patterning stage of manufacturing.

FIG. 4A depicts a portion of a mask with various square shaped meta-atoms having various pillar widths.

FIG. 4B depicts simulated geometries of fabricated meta-atoms of a portion of a metasurface, accounting for the impact of photolithographic and side-wall angle artifacts.

FIG. 4C is a graph of corner radius (in μm) as a function of pillar width due to photolithographic artifacts to incorporate corner radius data into simulation of the meta-atom shape, according to one embodiment of the present disclosure.

FIG. 4D is a graph of pillar width delta (in μm) as a function of pillar width due to side-wall angle artifacts to incorporate pillar width delta data into simulation of the meta-atom shape, according to one embodiment of the present disclosure.

FIG. 5A depicts examples of the geometries of nanopillars or meta-atoms having pillar widths of 50 nanometers (nm) and 320 nm, including: a) nominal geometries of the meta-atoms; b) geometries of the meta-atoms with side-wall angle (SWA) artifacts that produced obtuse side-wall angles; c) geometries of meta-atoms with rounded corners due to lithographic low-pass filtering in the spatial domain; and d) geometries of meta-atoms with both SWA artifacts and rounded corners.

FIG. 5B depicts post-fabrication simulation results of nano-pillars of various widths, where the simulated fabricated shapes of the nano-pillars are included in a library of manufacturing-aware meta-atoms, according to one embodiment of the present disclosure.

FIG. 5C is a graph showing phase accumulation in degrees as a function of pillar width for each of the meta-atom geometries shown in FIG. 5A, including: a) nominal pillars; b) pillars with the rounded corner effect (corner effect); c) pillars with the side-wall angle effect (Side Wall Angle effect); and d) pillars with both the rounded corners and side-wall angle effect (Corner and SWA effect).

FIG. 6 is a schematic depiction of a design aware flow for designing a metalens, according to one embodiment of the present disclosure.

FIG. 7A is a schematic depiction of an isolated meta-atom in the form of a nanoscale pillar according to one embodiment of the present disclosure.

FIG. 7B is a schematic depiction of a meta-atom in a local context of other meta-atoms in the form of nanoscale pillars according to one embodiment of the present disclosure.

FIG. 7C is a schematic depiction of meta-atoms in the form of nanoscale pillars in a full context of a metasurface according to one embodiment of the present disclosure.

FIG. 8A is a flowchart of a method for manufacturing-aware generation of a metasurface design according to one embodiment of the present disclosure.

FIG. 8B is a flowchart of a method for generating a library of manufacturing-aware meta-atoms based on simulation according to one embodiment of the present disclosure.

FIG. 8C is a flowchart of a method for generating a library of manufacturing-aware meta-atoms based on simulation and parameterization according to one embodiment of the present disclosure.

FIG. 8D is a flowchart of a method for generating a library of manufacturing-aware meta-atoms based on fabrication of meta-atoms and capture of images of the fabricated meta-atoms according to one embodiment of the present disclosure.

FIG. 9 depicts a diagram of an example computer system in which embodiments of the present disclosure may operate.

### DETAILED DESCRIPTION

Aspects of the present disclosure relate to optical and manufacturing aware design flow for metasurfaces.

Metasurfaces such as electromagnetic metasurfaces (or optical metasurfaces), fluid metasurfaces, or acoustic metasurfaces, are surfaces that are patterned with sub-resolution features, such as features smaller than the wavelength of the electromagnetic radiation or acoustic waves that these metasurfaces interact with. For example, a metalens may be formed by patterning nanoscale pillars of material (e.g., silicon nitride Si₃N₄ or titanium nitride TiN) onto a glass substrate (e.g., amorphous silicon dioxide SiO₂). In a case of a metasurface designed to interact with visible light, the nanoscale pillars may be, for example, about 650 nanometers (nm) tall and may range from about 90 nm to 350 nm in diameter (or pillar width), such that the diameters of these nanoscale pillars are smaller than the wavelength of visible light (e.g., about 380 nm to about 750 nm). For example, the nanoscale pillars may be built from thin films having a thickness ranging from 200 nm to 2,500 nm or more. Changing the pillar width changes the transmission and phase delay accumulated by light interacting with a given nanoscale pillar. Accordingly, by varying the pillar widths and the shapes of the nanoscale pillars in those different portions of the metalens, light that is incident on different portions of a metalens can be subjected to different amounts of transmission and phase delay. A metalens fabricated with an appropriate pattern of nanoscale pillars of different widths focuses light with performance comparable to that of a refractive lens, but in a smaller mass and volume. For example, a fabricated metalens may be a few microns in thickness. Furthermore, the thinness of individual metalenses and metasurfaces allows multiple metalenses and/or metasurfaces to be stacked into an optical system that still has a very small overall volume in comparison to optical systems composed of, for example, refractive lenses.

As such, metasurfaces such as metalenses enable drastic miniaturization of imaging systems like electric vehicle cameras, smartphones, and various other micro-camera applications, including augmented reality (AR) and virtual reality (VR) hardware. Large area metalenses (range of mm for the diameter and above) can also be used in interferometry, imaging, and outer space applications.

Although metalenses are a promising conceptual advance in scaling down the size of optical systems, designing metalenses for specific applications and preparing those designs for high volume manufacturing is a challenging process. A design process may include selecting an appropriate meta-atom (having a corresponding shape and shape parameters, as applicable, such as pillar width) to place at each location in the metalens or metasurface, such that the meta-atoms of the metalens or metasurface, as a whole, produce a desired optical effect (e.g., designing a metalens to focus light in accordance with a particular focal length). High volume manufacturing of metalenses may be performed using microfabrication techniques, including photolithography and reactive ion etching (RIE), to fabricate the nanoscale features onto an appropriate substrate (e.g., glass or mirrors). However, the design process includes challenges including problems such as metalens design, mask manufacturing for photolithography, layout generation, and the impact of the substrate flatness. Many of these factors depend on capabilities and limitations of the manufacturer (e.g., physical limitations of equipment in the microfabrication facility). These problems include discrepancies between nominal shapes (e.g., as modified based on shape parameters) of the meta-atoms and the actual shapes in the fabricated metalenses or metasurfaces, which causes the actual optical effect of the fabricated device to deviate from the designed optical effect.

Therefore, aspects of embodiments of the present disclosure relate to systems and methods for the design of metalenses and other optical metasurfaces that integrate a manufacturing-aware approach.

In more detail, the nanoscale features of the metasurface may be formed based on a library of meta-atoms. For example, a library of meta-atoms may include pillars having a square cross-section, where different pillars have different widths (e.g., different cross-sectional areas). Another library of meta-atoms may have pillars with circular cross-sections. Other libraries of meta-atoms may include pillars having rectangular-shaped, X-shaped, or H-shaped cross sections, without limitation to any design for the libraries of meta-atoms. Some libraries may include combinations of different shapes (e.g., circular shapes and X-shapes).

Due to limitations in the microfabrication processes for manufacturing metasurfaces, including metalenses, the fabricated nanoscale features generally do not match the idealized or nominal geometries as represented in the library of meta-atoms and exhibit various artifacts arising from the fabrication processes. Generally, corners will be more rounded, and the sidewalls of the pillars will be oblique to the substrate (e.g., not perfectly perpendicular the substrate, such as a glass substrate, that the pillars are formed on). These artifacts generally cause the fabricated optical metasurface to underperform compared to the theoretical performance of an idealized metalens (e.g., where the pillars have nominal shapes where the corners that are square or sharp and where the sidewalls of the pillars are straight and perpendicular to the substrate). Additional types of artifacts or differences from the idealized geometries of the nominal pillars include, but are not limited to, impurities and variations (e.g., the nanoscale features may be made of silicon nitride or Si₃N₄ where the feedstock of silicon nitride may be contaminated with silicon dioxide SiO₂, thereby changing the refractive index n and extinction coefficient k slightly), or mask write errors.

Therefore, aspects of embodiments of the present disclosure relate to generating a manufacturing-aware library of meta-atoms that are more representative of the geometry of the fabricated or manufactured meta-atoms, and then performing a subsequent design flow to generate computer-readable instructions for optimizing the metasurface design based on the simulated manufactured or manufacturing-aware meta-atoms. The manufacturing-aware meta-atoms are used by the design and optimization process (using software such as Synopsys® MetaOptic Designer) to achieve desired metasurface properties such as focal distance, lens diameter, and maximum absolute focal efficiency in a metalens. While aspects of embodiments of the present disclosure are presented herein in the context of a metalens designed to focus light, embodiments of the present disclosure are not limited thereto and are also applicable to designing metalenses that perform other or additional optical functions such as beam splitting, polarization filtering, wavelength-based focus position along spatial dimensions, edge highlighting, and the like.

Technical advantages of embodiments of the present disclosure include, but are not limited to, enabling a manufacturing aware design flow for designing optical metasurfaces that brings a manufactured metalens close to the idealized metalens performance for a given design of the nanoscale features. Use of a manufacturing-aware library of meta-atoms allows the design flow (or design process) to account for the actual geometries of the fabricated meta-atoms, rather than for the design process to perform simulations and optimizations based on idealized geometries that are unaligned with the realities of fabrication processes. As fabrication technologies improve and change, the manufacturing-aware meta-atom library is updated to account for these changes in the geometries of the fabricated meta-atoms, thereby allowing the design to automatically be updated in accordance with these changes. Embodiments of the present disclosure aid the implementation of design rules from and to optical and manufacturing design, thereby shortening the design cycle toward a target of a first design correct metalens (e.g., reducing the number of iterations of designing the optical metasurface, fabricating a prototype, testing the result, and revising the design, with the goal of reducing the number of iterations to a single iteration).

Aspects of embodiments of the present disclosure will be described herein in the example of designing a metalens based on forming silicon nitride (Si₃N₄) features (e.g., nanoscale pillars) on amorphous silicon dioxide (SiO₂) substrates. The pillar height in this example is 650 nm, the meta-atoms are arranged in a grid with a periodicity (e.g., period or center-to-center pitch) of 400 nm, and the design parameter or shape parameter is the pillar width (pw). Changing the value of this pillar width design parameter changes the transmission and the phase delay accumulated by the light. For example, the phase delay generally depends on the fill ratio of the periodic array, assuming constant height pillars, such that increasing the pillar width increases the phase delay. To increase control over the design of the metalens a library of meta-atoms provides meta-atoms that span a 360° (or larger) range of phase accumulations.

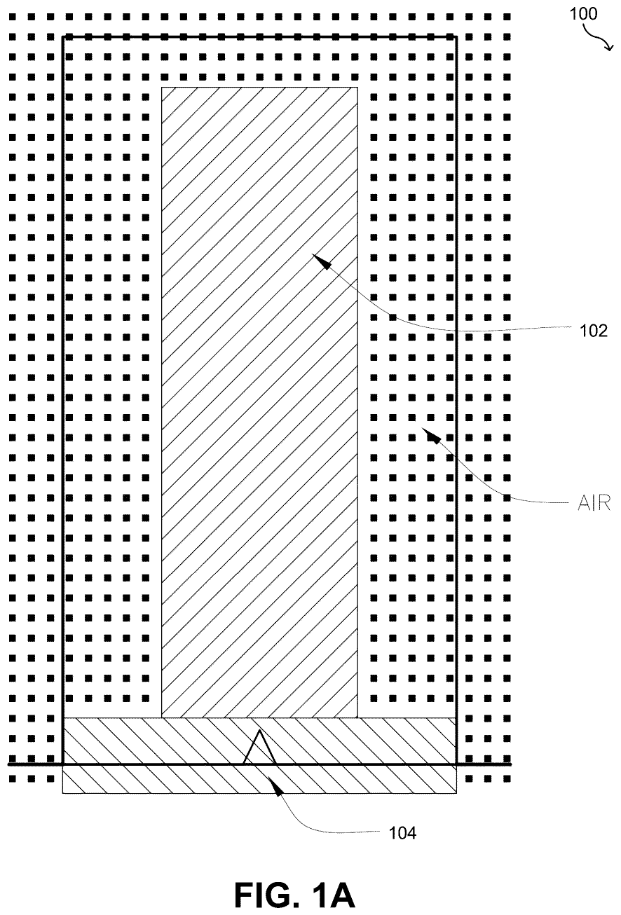

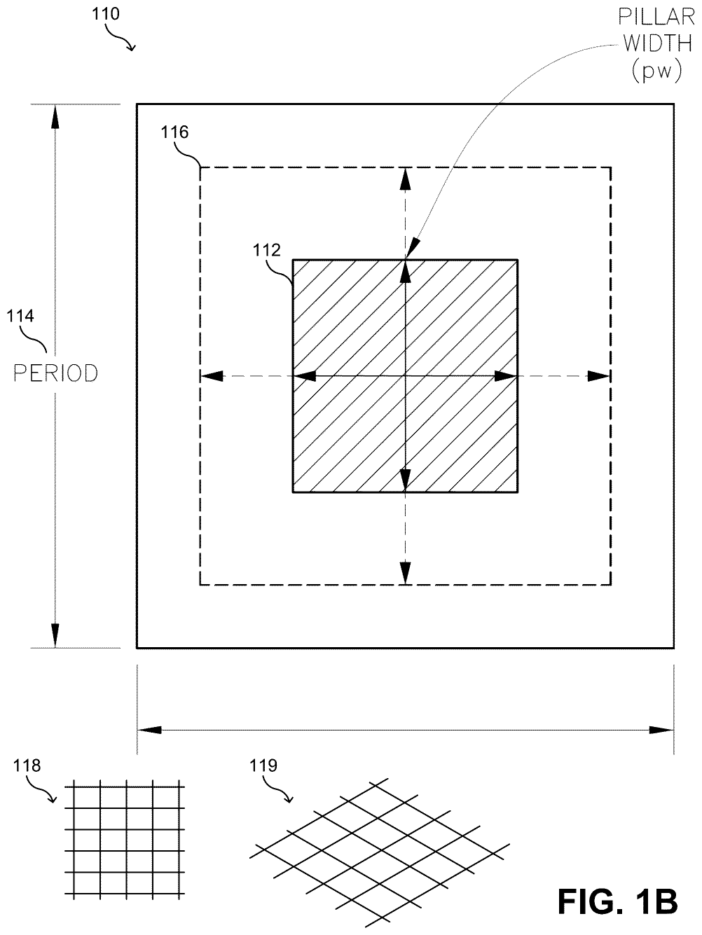

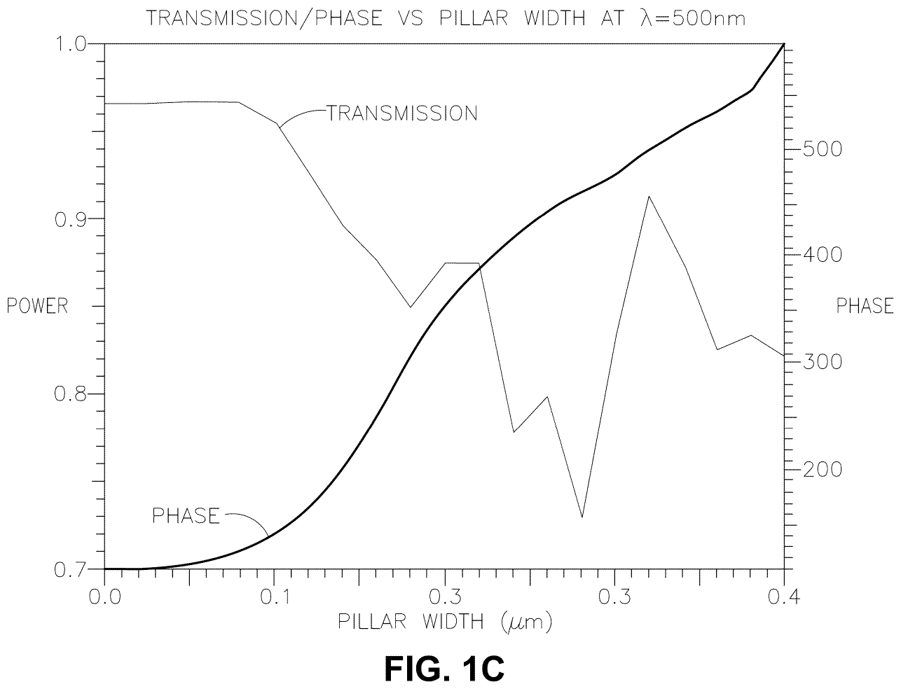

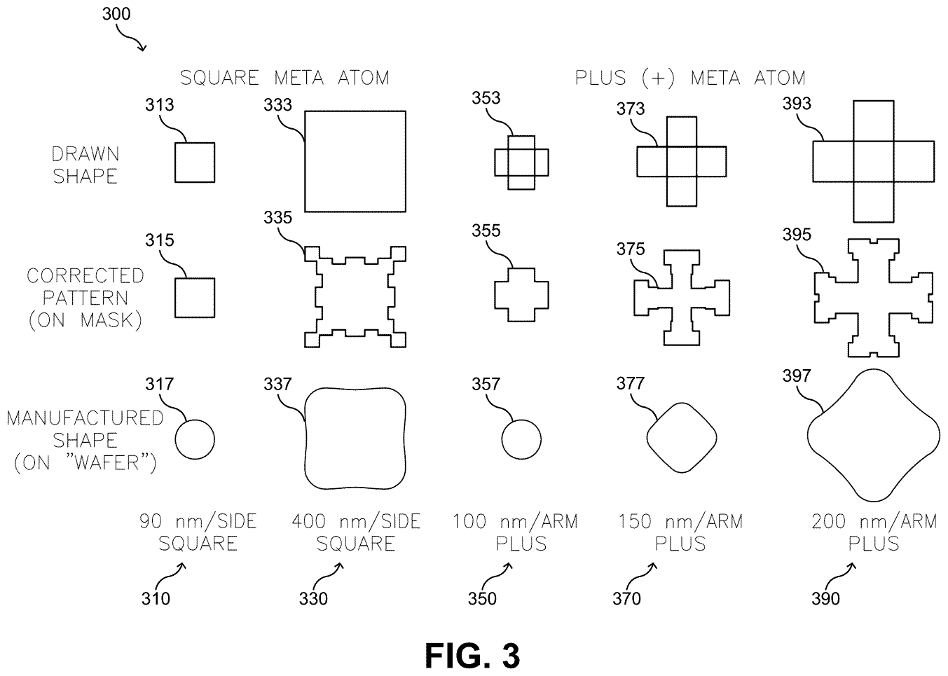

FIG. 1A is a schematic cross-sectional view of a nano-scale pillar 102 of a meta-atom 100 formed on a silicon dioxide (SiO₂) substrate 104. In the example of FIG. 1A, the space (indicated by dots) around the nano-scale pillar 102 is assumed to be air, but embodiments of the present disclosure are not limited thereto (e.g., in some applications, the space between the nano-scale pillars may be occupied by another fluid such as water or gases other than air, filled with a solid material having a different index of refraction than the pillar, or may be a vacuum). The nano-scale pillar 102 may have a pillar width (pw). FIG. 1B is a schematic plan view of a nano-scale pillar 112 of a meta-atom 110, illustrating the pillar width (pw) parameter. The example nano-scale pillar 112 of the meta-atom 110 shown in FIG. 1B has a square cross-section, although embodiments of the present disclosure are not limited thereto. The pillar width of the nano-scale pillar 112 can vary, such as between a smaller pillar width shown by the solid line shown at 112 and a larger pillar width 116 shown in FIG. 1B by the dashed line. The example nano-scale pillar shown in FIG. 1A and FIG. 1B is parameterized only by a pillar width because a pillar width is sufficient to describe the square cross-section. Similarly, a pillar width may be a sufficient shape parameter to describe a nano-scale pillar having a circular cross-section. However, embodiments of the present disclosure are not limited to these cross-sectional shapes. For example, FIG. 3, described in more detail below, shows examples of meta-atoms having plus (+) shaped nano-scale pillars (353, 373, and 393) which may be defined by a cross-arm length (e.g., corresponding to the size of the arms along their longer dimension) and a cross-arm width (e.g., corresponding to the size of the arms along their shorter dimensions). Nano-scale pillars having rectangular or oval cross sections may have two shape parameters: a length (or major axis) parameter and a width (or minor axis) parameter.

In some embodiments, meta-atoms 110 may be spaced apart from one another at a regular or uniform spatial distance or period 114. As noted above, in some embodiments the spatial period may be 400 nm. The grid may be a square grid 118 or may be an angled grid 119. In addition, in some embodiments the grid may be a hexagonal grid or another grid shape that can be tiled over a plane. The shapes or footprints of the meta-atoms are not necessarily regular polygons, such as in footprints of the meta-atoms in the angular grid 119, which are not equiangular, and such as in the case of a rectangular grid where the footprints of the meta-atoms may have different length versus width dimensions.

FIG. 1C is a graph depicting how transmission and phase vary with respect to the pillar width of the nano-scale pillar or meta-atom. This graph was produced using a computer simulation of the behavior of these nano-scale pillars. As shown in FIG. 1C, the phase accumulated over the scan of the pillar width up to 400 nm ranges from ˜100° to ˜600°. Accordingly, a library of meta-atoms with square cross-sections (as shown in FIG. 1B) and having pillar widths ranging from 90 nm to about 360 nm would provide a range of phase accumulations from about 140° to about 540° (enabling a designer to select from a range of phase accumulation of about) 400°.

To illustrate embodiments of the present disclosure, four example metalenses having different characteristics are described herein, as summarized in Table 1, below, along with their respective transmission, intensity match, and absolute focusing efficiency (AFE) theoretical performance metrics of metalenses composed of idealized meta-atoms (e.g., where the pillars have corners that are square and where the sidewalls are perpendicular to the substrate).

TABLE 1

| | Metalens 1 | | Metalens 2 | Metalens 3 | | Metalens 4 |
|---|---|---|---|---|---|---|
| Diameter (D) | 50 | μm | 100 μm | 500 | μm | 1 mm |
| Focal | 250 | μm | 500 μm | 2.5 | mm | 5 mm |
| distance (f) | | | | | | |

| | | | | |
|---|---|---|---|---|
| Transmission | 70.1% | 80.9% | 83.3% | 87.1% |
| Intensity Match | 89.4% | 92.7% | 96.0% | 96.7% |
| AFE | 65.7% | 75.9% | 76.4% | 77.2% |

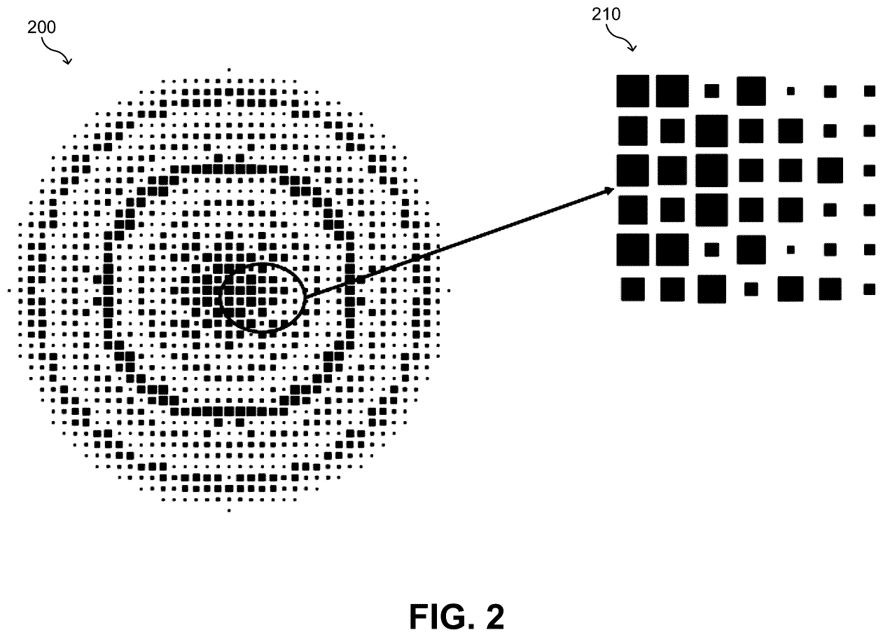

In more detail, to produce the results above, the meta-atom library was supplied to metalens design flow software that optimizes meta-surface arrangement for diverse and complex target types. All these optimized metalenses are designed to have a fixed f number of f/5 at 500 nm using normal incidence. The optimization performed by the metalens design flow presented here only changes the diameter of the lens D, and the corresponding focal distance f. The optimization attempts to hold a constant value for the Focusing Metric Diameter=12.2 nm (2*Airy Disk). FIG. 2 is an example of a mask layout of a metalens 200 produced by the metalens design flow, according to one embodiment of the present disclosure. As shown in FIG. 2, the pillar widths of the nano-scale pillars varies approximately based on distance from the center of the metalens 200, such that light incident on different parts of the metalens 200 are subject to different amounts of phase accumulation, thereby focusing the light in a manner to perform a similar optical function as a refractive lens or a Fresnel lens. FIG. 2 also includes an enlarged view 210 of a portion of the metalens 200, which helps to illustrate the spatially-periodic spacing of the meta-atoms and the varied pillar widths of the nano-scale pillars of the metalens 200.

A lens is defined by its f number and its capacity to maintain a good focusing efficiency which is referred to as the absolute focusing efficiency (AFE). The AFE is defined in Eq. (1) where I is the intensity normalized by the input intensity:

$$AFE = \int {\int }_{2 \times Airydisk} Idxdy \qquad ( 1 )$$

Other figures of merit including Transmission and Intensity Match may also be used to characterize a metalens. Transmission is defined as the ratio between the power at the image plane and the input power. The Intensity Match is defined in Eq. (2) where low is the intensity of the output field and I_{desired} is the intensity of the desired field over the domain:

$$Intensity Match = 1 - \frac{{I}_{out} - {I}_{desired}}{{I}_{out} + {I}_{desired}} \qquad ( 2 )$$

As noted above, in practice, a fabricated meta-atom on a physical substrate (e.g., fabricated on an amorphous silicon dioxide substrate) does not match the geometry of its idealized theoretical counterpart (referred to herein as a nominal meta-atom). The manufacturing process (e.g., microfabrication process) impacts the final geometry of each meta-atom. The two processes or process steps that have a large impact on the geometries of the fabricated meta-atoms are photolithography (also referred to as lithography) and reactive ion etch (also referred to as RIE or etch). The lithography process forms the shape (e.g., plan-view shape) of the designed meta-atom in a polymer film called a photoresist (e.g., projects light onto the photoresist in accordance with a pattern) and portions of the photoresist are removed based on the exposure to light (in the case of a positive photoresist, light weakens the polymer film, thereby creating a hole, whereas in the case of a negative photoresist, light toughens the resist, such that unexposed portions can be removed). The reactive ion etch process or etch process then removes material from the layer below the photoresist where photoresist is absent (or not present) on the substrate (e.g., in regions where the photoresist is not protecting the underlying material).

Both the lithography process stage and etch process stage impact the geometric fidelity of the manufactured device (e.g., the correlation between the idealized shapes of the nano-pillars and the actual physical shapes of the nano-pillars). The photolithography process stage uses a set of lenses between an illuminator and a wafer substrate (e.g., a glass or SiO₂ substrate in the case of a metalens) called the projection optics (PO). A patterned mask between the illuminator and the wafer selectively blocks or shades specific parts of the wafer substrate from light emitted by the illuminator, where the mask is designed with a shape corresponding to the pattern of meta-atoms of the design (see, e.g., the example mask shown in FIG. 2). For example, in the case of pillar-shaped meta-atoms with square cross sections, the mask may have a pattern of square holes of various widths (e.g., corresponding to the pillar widths of the library). The PO reduces the size of the pattern on the mask, generally by 4×, which allows a lower fidelity mask to image smaller structures (e.g., smaller pillar widths). One side effect of the PO is that the image transfer through the PO acts as a low pass filter which removes high spatial frequency components from the image that is incident on the wafer. This results in loss of image fidelity such as causing sharp corners to appear on the substrate as rounded corners (because the sharp corner contains high spatial frequency components). This, in turn, affects the shape of the photoresist that remains when the etch process occurs. (For example, even though the mask may have holes with square corners, the plan view of the image of the corresponding shape on the substrate will have rounded corners).

The examples described herein are based on a lithography process using a 193 nm wavelength scanner with a 0.85 numerical aperture (NA) PO. The lithography process uses a positive tone photoresist and a chrome patterned binary mask. This process is modeled in software to produce a three-dimensional image of the patterned meta-atom. However, embodiments of the present disclosure are not limited thereto and also may be applied to lithography processes using scanners with longer wavelengths (e.g., 248 nm) or shorter wavelengths and using projection optics having different values of NA. Furthermore, embodiments of the present disclosure are applicable to fabrication processes that use negative photoresist and masks other than a chrome patterned binary mask.

In addition, as noted above, embodiments of the present disclosure are not limited to capturing manufacturing artifacts arising from manufacturing processes using photolithography. For example, other patterning methods, such as nanoimprint lithography, talbot lithography, and electron-beam (e-beam) lithography, may cause different corresponding artifacts or deviations from the nominal geometries of the meta-atoms (e.g., the nano-scale pillars). Furthermore, other steps in manufacturing processes, such as deposition and chemical-mechanical polishing (CMP) steps may result in other types of manufacturing artifacts (e.g., other deviations from the nominal shapes of the structures), which may be modeled and accounted for according to various embodiments of the present disclosure, as discussed in more detail below.

FIG. 3 provides examples 300 of how square meta-atom and plus meta-atom shapes are impacted by a photolithography stage of manufacturing. As shown in FIG. 3, the smaller square shaped meta-atom 310 with a pillar width of 90 nm may be idealized as a drawn square shape 313 and represented as a corresponding square shape 315 in the mask, but the fabricated or manufactured plan-view shape 317 of the smaller square meta-atom (on the wafer or substrate) is nearly circular due to the low pass filtering of the image (causing rounding of the sharp corners). The larger square shaped meta-atom 330 with a pillar width of 400 nm has an idealized drawn square shape 333 has a different shape 335 on the mask (e.g., to account for some optical effects such as diffraction and light leakage at the edges of the mask, which may be referred to optical proximity correction or OPC), and the resulting manufactured plan-view shape 337 of the larger square meta-atom is generally a square with rounded corners (there may also be some waviness on the sides of the square). Similarly, cross or plus (+) shaped meta-atoms 350, 370, and 390 are shown with corresponding sizes of 100 nm width arms, 150 nm width arms, and 200 nm width arms. While the nominal shapes 353, 373, and 393 of the meta-atoms are plus-shaped, the corresponding masks of the meta-atoms with 150 nm and 200 nm width arms have modified shapes 375 and 395 (e.g., thinner near the crossing point) to account for optical effects (for optical proximity correction), and the resulting manufactured shapes differ from the nominal shapes, ranging from nearly circular 357 for the plus shape with 100 nm wide arms, to approximately rounded diamond shaped for the meta-atoms with the 150 nm wide arms 377 and 200 nm wide arms 397. (In the example of FIG. 3, the mask shape 355 of the meta-atoms with 100 nm width arms is not modified to be thinner at the crossing point, although embodiments of the present disclosure are not limited thereto.)

In addition, the etch process is not perfectly anisotropic which creates a side wall angle (SWA) that is oblique (e.g., not a right angle of 90° with respect to the substrate). Depending on various factors of the etch process stage applied in the microfabrication process a final SWA that has an oblique angle that is less than 90° with respect to the substrate (e.g., an acute angle) or greater than 90° with respect to the substrate (e.g., an obtuse angle), where an example of a range of SWA for some microfabrication processes is between 88° and 92°.

Etch process simulation software may simulate an etching in accordance with the mask patterns to produce a three-dimensional image of the Si₃N₄ nano-pillars of the meta-atoms to predict the manufacturing impact to corner rounding and SWA. Additional types of manufacturing artifacts include rounding of the top of the nano-scale pillars, overetching past the bottom of the (e.g., silicon nitride) nanopillar and into the (e.g., silicon dioxide) substrate, and surface roughness caused by the lithography and etch processes.

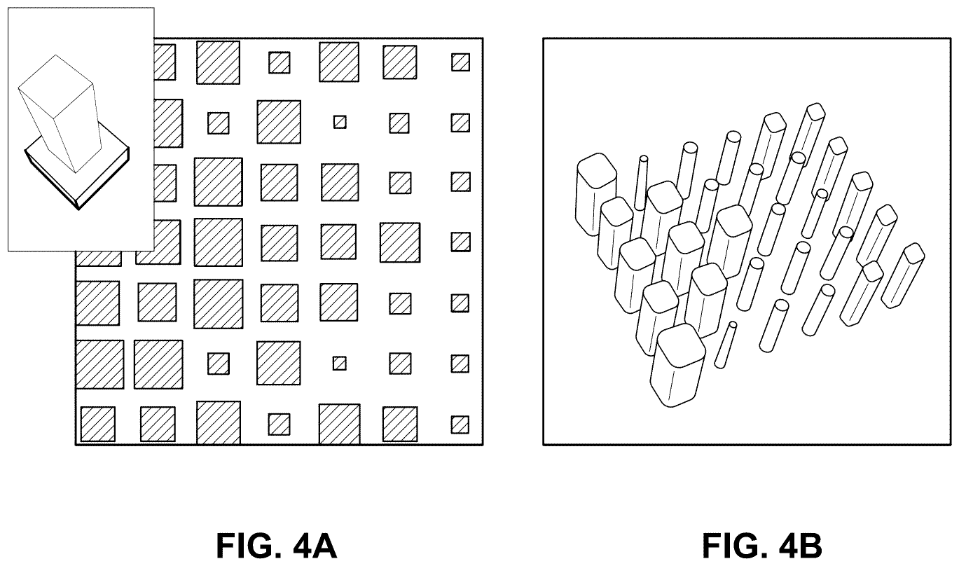

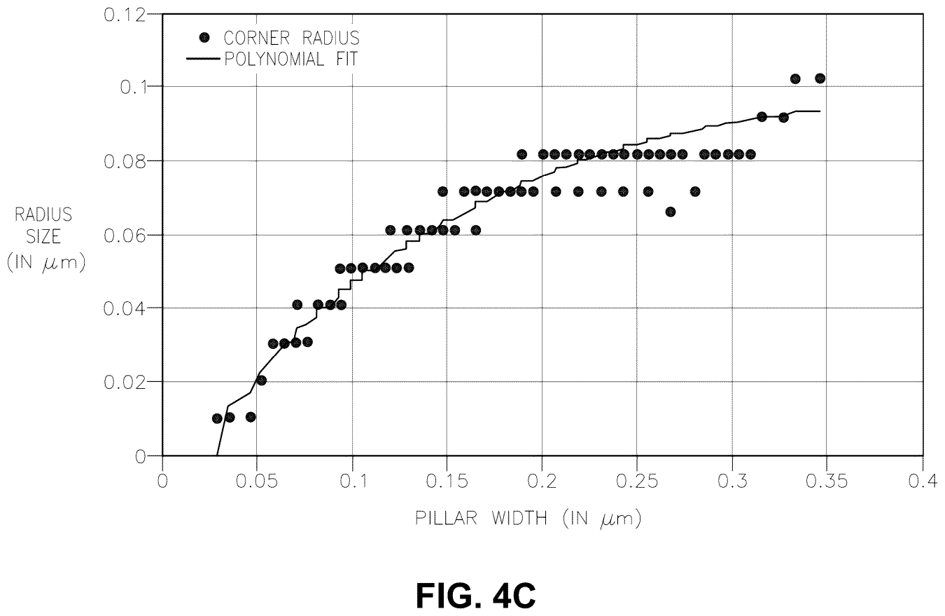

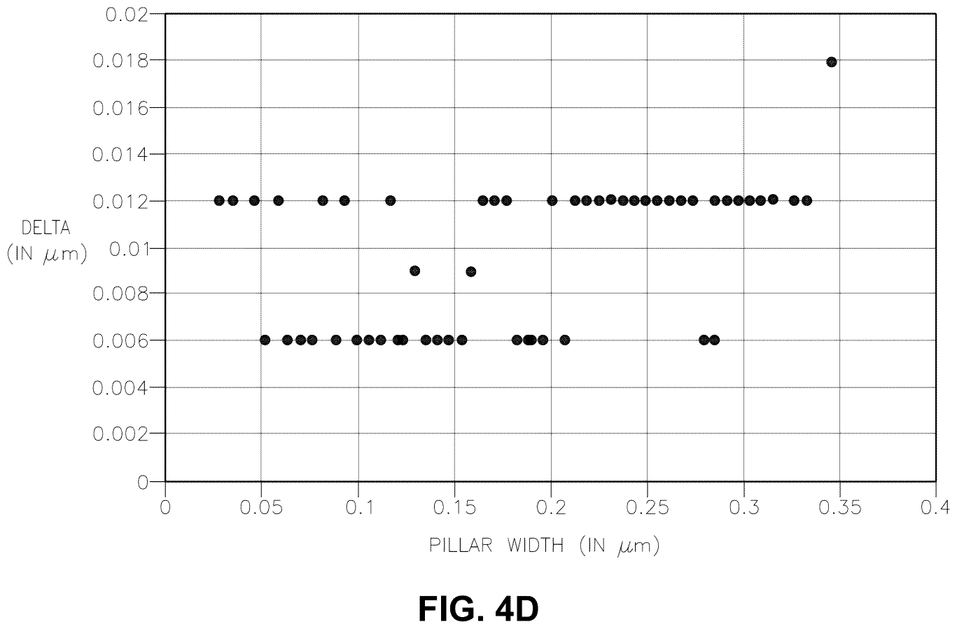

FIG. 4A depicts a portion of a mask with various square shaped meta-atoms having various pillar widths. An inset in FIG. 4A depicts the idealized three-dimensional shape of a meta-atom, where the nano-scale pillar has sharp corners and straight side-walls. FIG. 4B depicts simulated geometries of fabricated meta-atoms of a portion of a metasurface, accounting for the impact of photolithographic and side-wall angle artifacts, including rounded corners of the nano-scale pillars and side-wall angles that are oblique to the surface of the substrate (e.g., tapering toward the tops of the nano-scale pillars).

FIG. 4C is a graph of corner radius (in μm) as a function of pillar width due to photolithographic artifacts. FIG. 4D is a graph of pillar width delta (in μm) as a function of pillar width due to side-wall angle artifacts. These data can be used to make splines or other functions for parametric representations of the manufactured geometry of the meta-atom. For example, FIG. 4C shows that the corner radius of a pillar increases with the pillar width, and a polynomial curve can be fit to the data, thereby resulting in a parametric representation of a predicted radius size as a function of pillar width for a given process for manufacturing the nano-scale pillars of the meta-atoms. Parametric representations of the differences between the idealized geometries and the fabricated geometries, such as the photolithographic artifacts and side-wall angle artifacts due to etching, are advantageous as they are simple to calculate during optimization, thereby resulting in low runtime overhead, but may be less accurate than other representations, as described in more detail below.

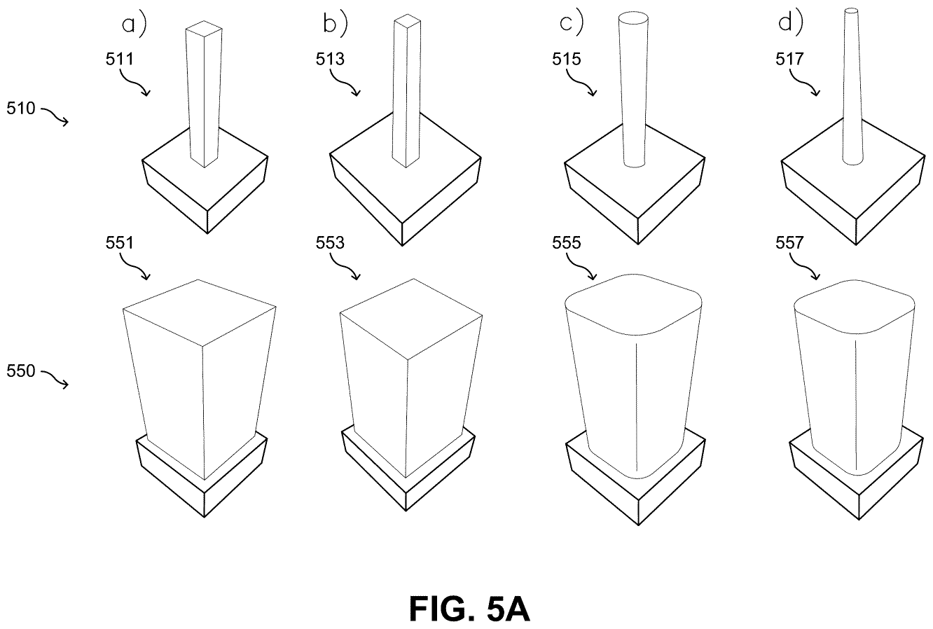

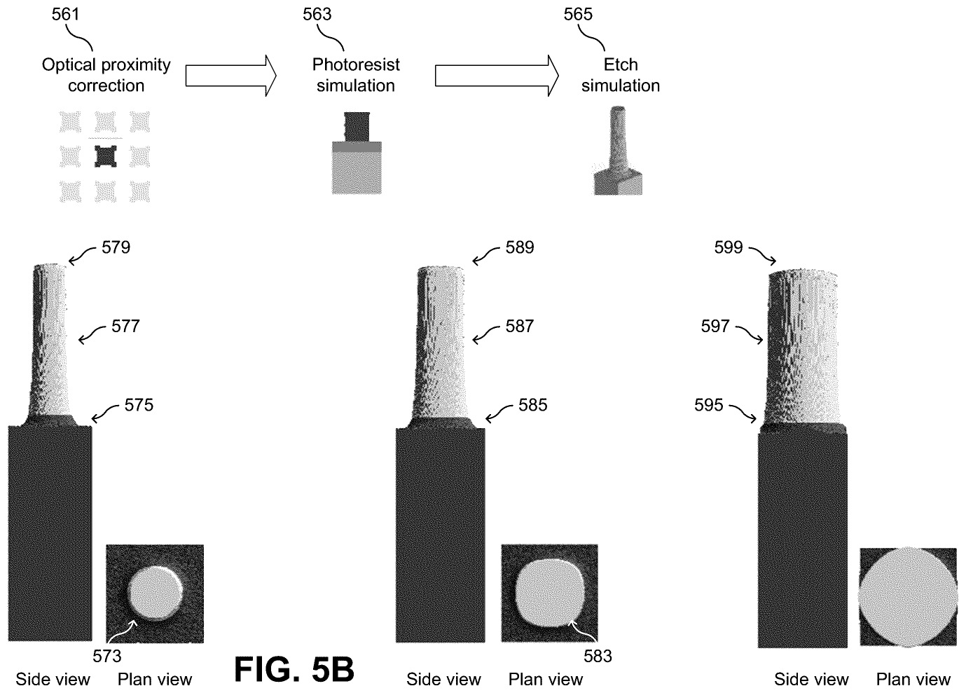

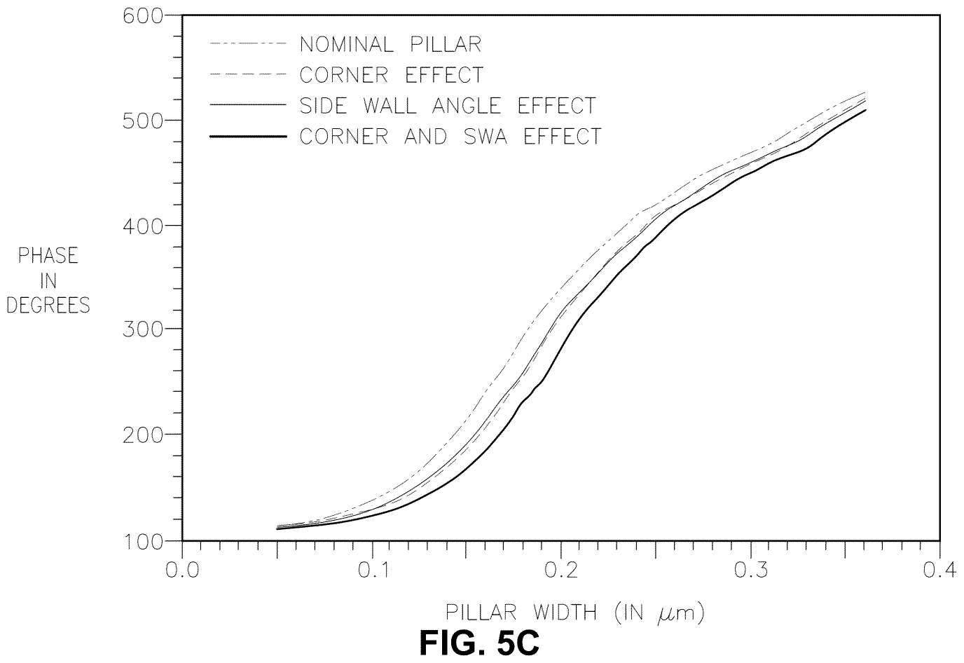

FIG. 5A depicts examples of the geometries of nanopillars or meta-atoms having smaller pillar widths 510 of 50 nm and larger pillar widths 550 of 320 nm, including: a) nominal geometries of the meta-atoms with the smaller pillar width shown at 511 and the larger pillar width shown at 551; b) geometries of the meta-atoms with side-wall angle (SWA) artifacts that produced obtuse side-wall angles with the smaller pillar width shown at 513 and the larger pillar width shown at 553; c) geometries of meta-atoms with rounded corners due to lithographic low-pass filtering in the spatial domain with the smaller pillar width shown at 515 and the larger pillar width shown at 555; and d) geometries of meta-atoms with both SWA artifacts and rounded corners with the smaller pillar width shown at 517 and the larger pillar width shown at 557.

FIG. 5B depicts post-fabrication simulation results of nano-pillars of various widths, where the simulated fabricated shapes of the nano-pillars are included in a library of manufacturing-aware meta-atoms, according to one embodiment of the present disclosure. As shown in FIG. 5B, simulating the fabrication of nano-pillars includes performing optical proximity correction (OPC) 561, photoresist simulation 563, and etch simulation 565. At optical proximity correction 561, the nominal shapes of the meta-atoms (e.g., square shapes) are replaced with OPC versions that account for optical effects such as diffraction, like the corrected patterns (on mask) shown in FIG. 3, where FIG. 5B shows corrected shapes for square meta-atoms. At photoresist simulation at 563, shape rounding (low pass filtering in the spatial domain) illustrated for example at 573 and at 583 is simulated. At etch simulation 565, the effects of the etch processes are simulated, which may include overetch shown at 575, 585, and 595 (etching into the substrate to ensure full etch of the nano-pillar) and fillets or rounding at the substrate from the etch (also illustrated at 575, 585, and 595), side-wall angle deviations from perpendicular to the substrate illustrated at 577, 587, and 597 caused by the photolithography and the etch process, surface roughness on the sides of the nano-pillars, caused by the photolithography and etch processes, and rounding of the tops of the nano-pillars, illustrated at 579, 589, and 599, caused by the etch process. These simulations produce three-dimensional models of the shapes of fabricated nano-pillars, that may be included in a library of manufacturing-aware meta-atoms for use in simulation of a metasurface design, as discussed in more detail below.

FIG. 5C is a graph showing phase accumulation in degrees as a function of pillar width for each of the meta-atom geometries shown in FIG. 5A, including: a) nominal pillars; b) pillars with the rounded corner effect (corner effect); c) pillars with the side-wall angle effect (Side Wall Angle effect); and d) pillars with both the rounded corners and side-wall angle effect (Corner and SWA effect). As seen in FIG. 5A, at relatively smaller pillar widths of about 50 nm (or 0.05 μm), the corner effect (caused by low-pass filtering in the spatial domain) and the side-wall angle effect (caused by etching) have relatively little effect on the phase accumulation. However, the differences between the idealized or nominal and pillars exhibiting the corner effect, the side wall angle effect, or both effects become substantial as the pillar width increases. For example, at a pillar width of 200 nm, the nominal or idealized shape of the nano-pillar is expected to cause about 340° of phase accumulation. However, nano-pillars exhibiting only one of the rounded corner effect and the side-wall angle effect are expected to cause only about 310° of phase accumulation, and simulated nano-pillars with a pillar width of 200 nm exhibiting both the rounded corner effect and the side-wall angle effect are expected to cause only 280° of phase accumulation. As such, metalens design workflows that do not account for fabrication process effects such as corner rounding and side-wall angles can produce simulation results that diverge from measured results of a fabricated metalens.

Due to these deviations in phase angle between the nominal meta-atoms (e.g., nominal pillars a) of FIG. 5A) and manufactured meta-atoms (e.g., pillars d) of FIG. 5A), there is an expected difference or fidelity loss arising from artifacts of the lithography process stage and etch process stage. This fidelity loss may be defined in Equation (3) as:

$$Fidelity Loss = 1 - \frac{{AFE}_{pertubation}}{{AFE}_{nomìnal}} \qquad ( 3 )$$

To analyze the effects of these deviations in practical metalens designs, the techniques described above were used to generate three additional libraries of meta-atoms based on a library of nominal meta-atoms. The first additional library includes meta-atoms exhibiting the side-wall angle (SWA) artifacts resulting from the etching process represented by schematic in b) of FIG. 5A; the second additional library includes meta-atoms exhibiting the photolithography artifact related to the corner radius in c) of FIG. 5A; and a third additional library includes meta-atoms exhibiting both the SWA artifacts and rounded corner artifacts as shown in d) of FIG. 5A.

The performance of the generated layout for metalenses 1, 2 3 and 4 (described above with respect to Table 1) using the definitions of meta-atoms a), b), c), and d) from FIG. 5A. The results of the AFE of the various scenario of design rules are provided in Table 2, below. In more detail, all of the examples shown in Table 2 use the same layout, as generated based on the nominal meta-atoms (library a), and where the performance (AFE) is evaluated using simulations where the meta-atoms in that generated layout are replaced with corresponding meta-atoms exhibiting manufacturing artifacts in accordance with libraries b), c), and d), without changing the layout itself.

TABLE 2

| | Metalens 1 | Metalens 2 | Metalens 3 | Metalens 4 |
|---|---|---|---|---|
| AFE using | 65.7% | 75.9% | 76.4% | 77.2% |
| Library a) | | | | |
| (nominal) | | | | |
| AFE using | 63.5% | 71.7% | 71.6% | 72.3% |
| Library b) | (Fidelity loss | (Fidelity loss | (Fidelity loss | (Fidelity loss |
| (SWA) | 3.3%) | 5.5%) | 6.3%) | 6.3%) |
| AFE using | 63.5% | 71.7% | 71.5% | 72.3% |
| Library c) | (Fidelity loss | (Fidelity loss | (Fidelity loss | (Fidelity loss |
| (Corner | 3.3%) | 5.5%) | 6.4%) | 6.3%) |
| Rounding) | | | | |
| AFE using | 60.1% | 64.7% | 63.4% | 64.0% |
| Library d) | (Fidelity loss | (Fidelity loss | (Fidelity loss | (Fidelity loss |
| (Corner | 8.5%) | 14.8%) | 17%) | 17.1%) |
| Rounding + | | | | |
| SWA) | | | | |

As shown in Table 2, both SWA artifacts (exhibited, e.g., by the metalens created using library b) and rounded corner artifacts (exhibited, e.g., by the metalens created using library c) impact the efficiency of the metalenses in approximately equal proportion. This equivalent impact may be explained by the phase delay definition of those meta-atoms library: in FIG. 5C, the phase definition is almost the same for the meta-atoms having the etch predicted by the process and the meta-atoms having rounded corners.

However, combining these two effects or artifacts in meta-atoms library d), the AFE fidelity loss increases more than linearly (the penalty increase is greater than the accumulation of the two penalties.) For example, considering Metalens 1, the AFE fidelity loss due to SWA artifacts alone (as exhibited by meta-atom library b) is 3.3% and the AFE fidelity loss due to corner rounding artifacts alone (as exhibited by meta-atom library c) is also 3.3%. Assuming a linear combination of these two effects would suggest a combined AFE fidelity loss of 3.3%+3.3%=6.6%. However, the AFE fidelity loss when the meta-atoms exhibit both SWA artifacts and corner rounding artifacts (as exhibited by meta-atom library d) is 8.5%. This means that even if some effects have individual low impacts on the AFE, the manufacturing effects together might have a more significant compound impact.

As such, the manufacturing process has a significant impact on the final meta-atom geometry, which, in turn, impacts the performance of the metalens, as discussed above with respect to Table 2. Therefore, aspects of embodiments of the present disclosure relate to bringing the manufacturing process into the meta-atom during the process of designing the metalens to reduce the impact of manufacturing deficiencies on the metalens performance.

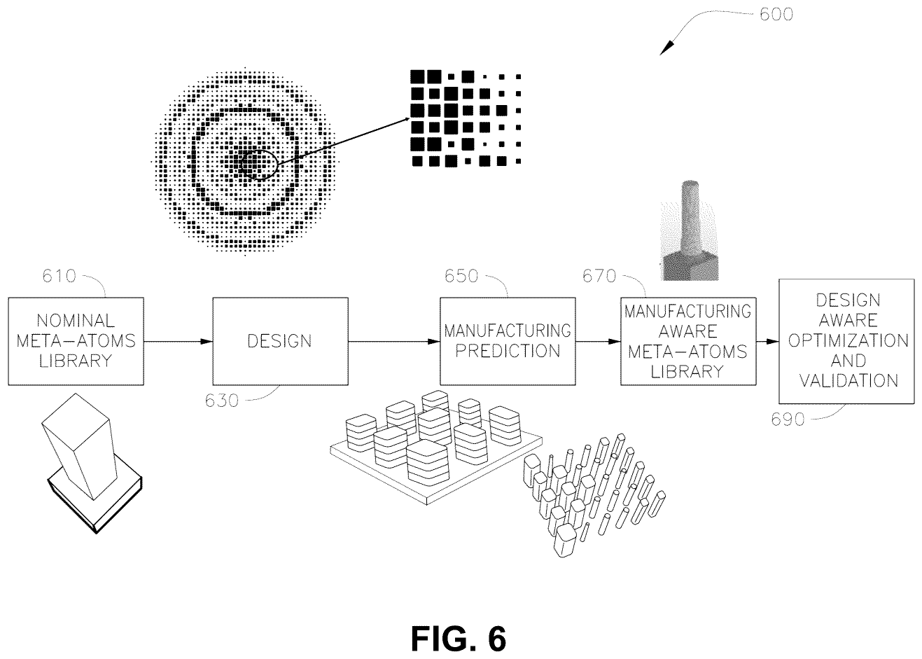

FIG. 6 is a schematic depiction of a design aware flow 600 according to one embodiment of the present disclosure. As shown in FIG. 6, an initial nominal meta-atoms library 610 (e.g., a library of idealized meta-atoms that do not exhibit manufacturing artifacts such as oblique side-wall angles and rounded corners) is used to create a design 630 of a metasurface such as a metalens. Manufacturing prediction at 650 is used to generate a manufacturing-aware meta-atoms library 670, where the manufacturing-aware meta-atoms library 670 exhibits manufacturing artifacts in accordance with the manufacturing prediction 650. The geometries of the manufacturing-aware meta-atoms may be specific to the microfabrication process targeted for fabricating the metasurface, such as wavelength of a scanner used during a photolithography process stage and chemistry of the material used to form the meta-features (e.g., the nano-pillars) such as silicon nitride (Si₃N₄) and its interactions with the etchant used during an etching process stage. A given shape of the nano-pillar of a meta-atom is analyzed at multiple pillar widths (e.g., 50 nm, 100 nm, 150 nm, etc.).

In some embodiments of the present disclosure, the shapes of the nano-pillars are predicted using rule-based methods. As previously discussed with respect to FIG. 4C and FIG. 4D, in some embodiments, a collection of data samples regarding the shapes of nano-pillars at different pillar widths (e.g., computed through simulation or through fabrication and subsequent measurement, such as through scanning electron microscopy), such as corner radius as shown in FIG. 4C and side-wall angle artifacts as shown in FIG. 4D, Best-fit or curves are fit to these data, and the resulting mathematical functions specifies rules for predicting a corner radius or a side-wall angle as a function of pillar width.

In some embodiments of the present disclosure, the manufacturing-aware shapes of the meta-atoms are computed by simulating of processes for fabricating the meta-atoms, such as in the case of the simulated fabricated nano-pillars shown and described above with respect to FIG. 5B. This approach based (three-dimensional) models computed from simulation of fabrication processes may be referred to herein as model-based correction, in contrast to the rule-based correction approach described above in relation to FIG. 4C and FIG. 4D.

In some embodiments of the present disclosure, these pillar width states are then collected in a library that is used to represent the structures of the meta-atoms during optimization and analysis of the design.

The resulting manufacturing-aware meta-atoms library 670 is then used to perform design aware optimization, analysis, and validation of the design at 690 (instead of using the nominal meta-atoms library 610). In more detail, the design aware metaatoms (which may be constructed from, for example: simulation; using the rule-based methods using the best-fit splines; from a critical dimension scanning electron microscope (CD-SEM) image; or the like) replace the nominal designed meta-atoms. These manufacturing aware meta-atoms are used in the metasurface optimization 690 rather than the nominal meta-atoms. During this optimization process, a cost function is evaluated on the design, such as to measure a difference between a desired or target behavior of the design and a simulated behavior of the design. Individual meta-atoms may then be automatically replaced (e.g., to increase or decrease the phase delay introduced by a particular part of the metasurface) to shift the behavior of the metasurface design closer to the target behavior (thereby reducing the value computed by the cost function) until the design converges. During validation, the output of the metasurface is simulated to verify that the behavior matches the target behavior. Using the manufacturing-aware meta-atoms improves the accuracy of the simulation results regarding the performance of the designed metasurface.

In some embodiments, the user does not directly see or interact with the manufacturing aware meta-atoms during the design and optimization phase 690. For example, the user may continue to think of the meta-atoms based on their nominal shapes, without considering the actual shapes of those meta-atoms when fabricated on the substrate.

In some embodiments, the user is presented with information and/or can modify the manufacturing aware meta-atoms during the design and optimization phase 690. For example, a user may note that no substantial change in behavior is seen when switching a particular meta-atom from having a square shape to a plus shape, where inspecting the meta-atom will reveal that, for the specified pillar width of that meta-atom, the manufacturing aware versions of the nominal square-shaped meta-atom and the nominal plus-shaped meta-atom have substantially the same shape (e.g., a circular shape, as shown at 317 and 357 of FIG. 3).

Accordingly, the design aware optimization and validation process 690 accounts for manufacturing artifacts such as side-wall angle (SWA) and corner rounding due to photolithography when generating a finalized design for controlling fabrication facility when manufacturing the metasurface (e.g., data defining masks for performing photolithography). Table 3, below, shows the results of using these manufacturing-aware meta-atoms in the optimization and analysis of the metalens design and compares these results with those using the nominal meta-atoms. In more detail, the first row of Table 3 shows the same AFE performance metrics for Metalens 1 through Metalens 4 as shown in Table 1 and Table 2, above. However, the second row of Table 3 shows the AFE performance for different layouts for Metalens 1 through Metalens 4 than the layouts from the first row of Table 3, where the different layouts are generated by performing design and optimization processes (e.g., as shown at 690 of FIG. 6) for the four different metalens designs using the manufacturing-aware meta-atoms.

TABLE 3

| | Metalens 1 | Metalens 2 | Metalens 3 | Metalens 4 |
|---|---|---|---|---|
| AFE using | 65.7% | 75.9% | 76.4% | 77.2% |
| nominal | | | | |
| meta-atom | | | | |
| library | | | | |
| AFE using | 64.8% | 75.6% | 77.9% | 78.4% |
| manufacturing | | | | |
| aware | | | | |
| meta-atom | | | | |
| library | | | | |

As shown in Table 3, above, using the manufacturing aware meta-atom library to perform design aware optimization and validation (e.g., with simulated manufacturing or post-manufacturing artifacts) produces results that are close to or exceed the theoretical performance (with respect to AFE) of ideal metalenses (e.g., as if manufacturing were perfect and did not produce manufacturing artifacts such as SWA and rounded corners due to low-pass filtering in the spatial domain). In other words, the optimization process is able to achieve real-world performance that matches or exceeds the performance of a metalens or metasurface with idealized nano-scale pillars (e.g., with perfect manufacturing).

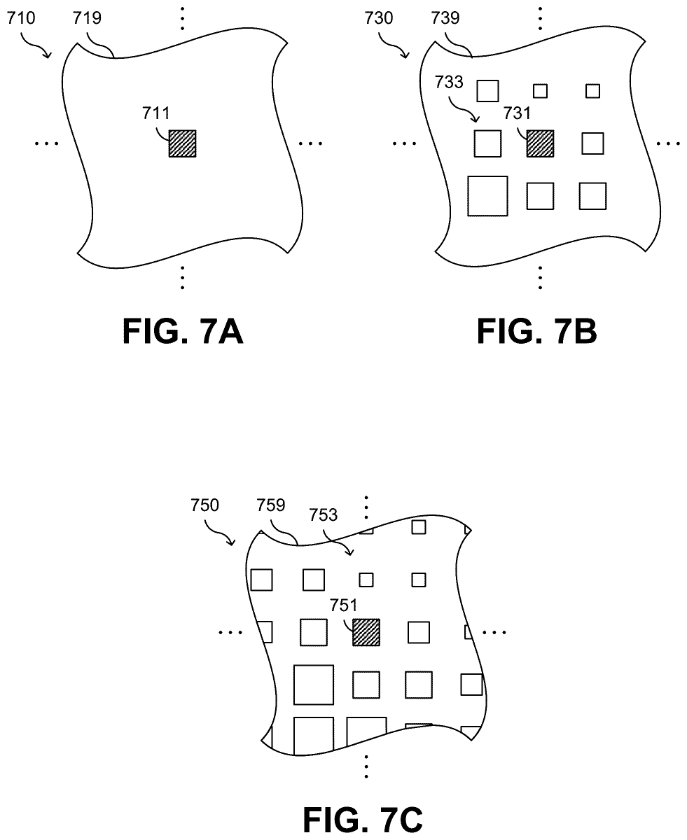

In the example discussed above, the manufacturing-aware meta-atom library was generated (e.g., during manufacturing prediction at 650 of the design aware flow 600) based on simulations of the effects of low-pass filtering of the shapes (e.g., in the mask) during photolithography and simulations of the SWA, such that the manufacturing-aware meta-atom library includes the three-dimensional geometries of the meta-atoms exhibiting simulated artifacts arising from the fabrication processes. These simulations may be performed based on isolated meta-atoms, such as the case of fabricating a single meta-atom at the center of the substrate. FIG. 7A is a schematic depiction of an isolated meta-atom in the form of a nanoscale pillar according to one embodiment of the present disclosure. In the substrate of 710, a single isolated meta-atom 711 is placed in the center of a region 719 with no other meta-atoms in the region.

The resulting three-dimensional geometries of the meta-atom may be complex and therefore may require substantial storage space. Accordingly, some aspects of embodiments of the present disclosure relate to representing the meta-atoms of manufacturing-aware meta-atom library as parameterized curves (such as Bézier curves, Bézier surfaces, and/or splines). A parameterized curve representation of the three-dimensional geometry of the meta-atom is much smaller and can be used to represent a range of meta-atoms (e.g., an input parameter relating to the pillar width may be used to control the geometry of the output Bézier surface representing the meta-atom).

In some embodiments of the present disclosure, the library of manufacturing-aware meta-atoms includes microscopic images of the nanoscale pillars, as may be captured using a scanning electron microscope (SEM). For example, in some embodiments, single isolated nanoscale pillars (e.g., spaced far enough apart to reduce or minimize interactions) are fabricated on a substrate (e.g., glass), and the resulting SEM images of the geometries of the isolated nanoscale pillars are stored as representations of the individual manufacturing-aware meta-atoms.

While a single isolated meta-atom is a convenient unit for developing a library of manufacturing-aware meta-atoms for designing and optimizing a metasurface design, in some microfabrication technologies (or manufacturing processes) light passing through a hole in the mask can also affect other parts of the substrate in a neighborhood of optical influence around the hole. For example, in the case of a 193 nm wavelength scanner, the neighborhood of optical influence (or optical ambit or model ambit, in the context of performing optical proximity correction or OPC) is about one micron (1 μm), where the strength of the influence decreases with distance from the opening. Accordingly, the context in which a meta-atom is formed (e.g., the geometries of the other meta-atoms in a neighborhood or local context around the meta-atom) can have an impact on the final fabricated geometry of the meta-atom of interest.

FIG. 7B is a schematic depiction of a meta-atom in a local context of other meta-atoms in the form of nanoscale pillars according to one embodiment of the present disclosure. The example of FIG. 7B, as with other examples above, assumes that the meta-atoms are arranged on a rectangular grid, although embodiments of the present disclosure are not limited thereto. In this case of a rectangular grid, a meta-atom of interest 731 has eight adjacent neighbor meta-atoms 733 in its local context 739 or partial context, where the shapes of these adjacent neighbor meta-atoms 733 can impact the fabricated geometry of the meta-atom of interest 731. For example, light diffracted onto the area of the meta-atom of interest 731 from the holes associated with the adjacent neighbor meta-atoms 733, in accordance with their pillar widths, can change the shape of the hole in the photoresist for the meta-atom of interest 731.

Like in the case of a single isolated meta-atom described above, the fabricated geometry of a meta-atom of interest 731 can be computed through simulation, taking into account the context 739 including the adjacent neighboring meta-atoms 733. A library of manufacturing-aware meta-atoms can therefore be generated for each meta-atom, including variations for the various possible arrangements of adjacent meta-atoms 733 (e.g., varying the pillar widths of the adjacent meta-atoms and/or varying the geometries of the adjacent meta-atoms if the library of nominal meta-atoms also has meta-atoms of different cross-sectional geometries). Rotational symmetry and reflectional symmetry may reduce the number of arrangements that need to be computed in cases where the manufacturing process itself is also symmetric. In addition, some of the intermediate sizes of pillar widths may be omitted in favor of interpolating between the known samples or selecting a closest match in order to trade off generating different geometries against performance (e.g., quality of the optimization and verification process at 690). In addition, some aspects of embodiments of the present disclosure relate to including additional meta-atoms from a local context or neighborhood around the meta-atom of interest 731, such as a next group of meta-atoms that are a step farther away from the meta-atom of interest (e.g., two grid spaces away, rather than directly adjacent). In a manner similar to that described above, the geometries generated through this process can be parameterized (e.g., represented as Bézier curves, Bézier surfaces, and/or splines) to reduce the storage requirements of the manufacturing-aware meta-atom library and increase optimization computational speed.

In addition, in a manner similar to that described above, SEM images can be captured of physically fabricated meta-atoms in a variety of different neighborhoods of adjacent meta-atoms, and the resulting SEM images may be included in the manufacturing-aware meta-atom library as representations of the geometries of the fabricated meta-atoms.

FIG. 7C is a schematic depiction of meta-atoms in the form of nanoscale pillars in a full context of a metasurface according to one embodiment of the present disclosure. As discussed above, the context in which a meta-atom is fabricated has an impact on the fabricated geometry of that meta-atom. While a local context or partial context in the form of adjacent neighboring meta-atoms to a meta-atom of interest can significantly improve the accuracy of the predicted shape of the meta-atom of interest, meta-atoms farther away than the adjacent neighboring meta-atoms can also impact the fabricated geometry of the meta-atom of interest. Accordingly, some aspects of embodiments of the present disclosure relate to performing simulations to compute the geometries of all of the meta-atoms of the metasurface design and supplying these computed geometries to the design aware optimization and validation process at 690 of FIG. 6.

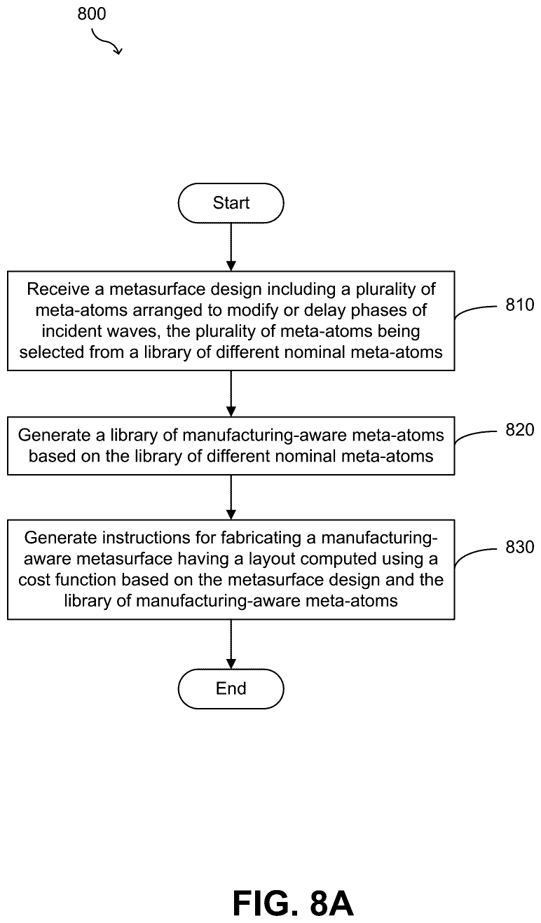

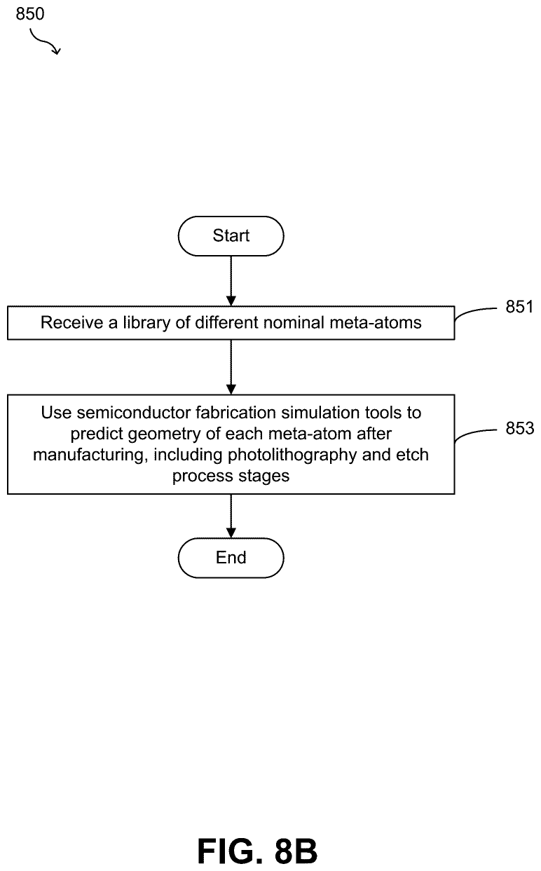

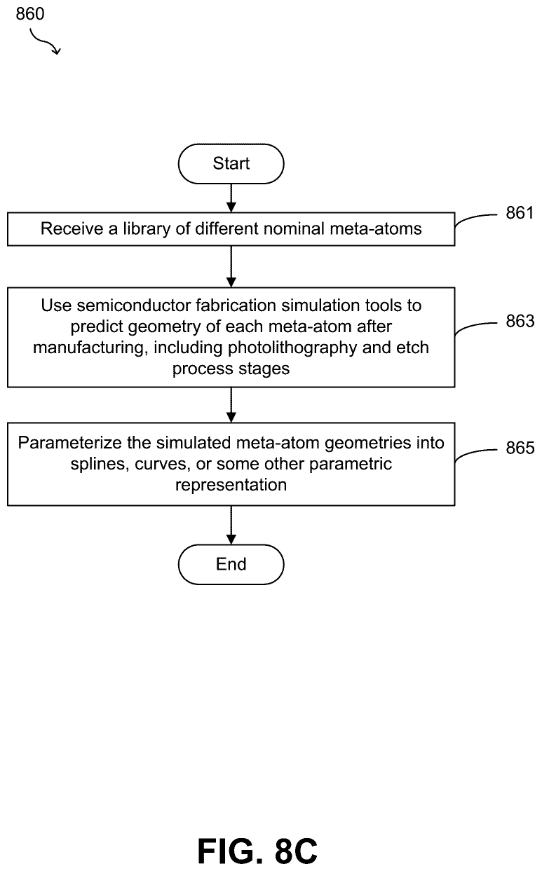

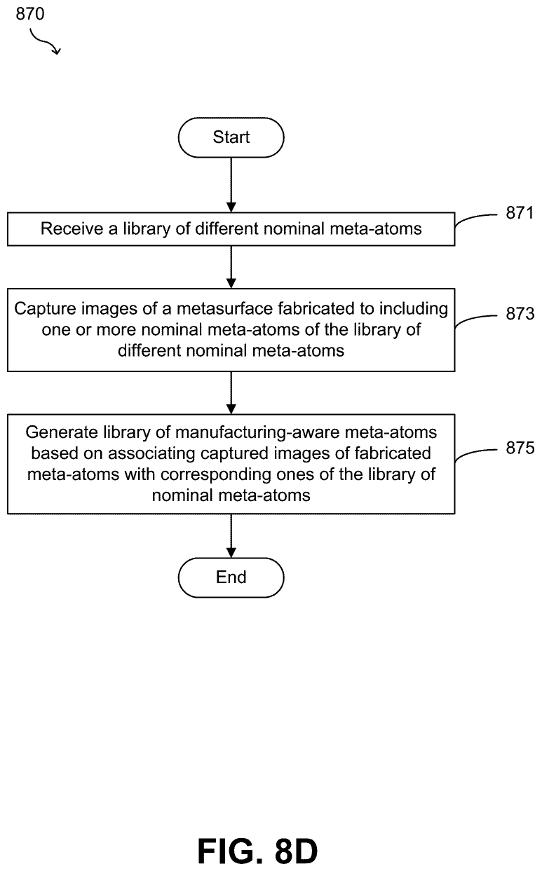

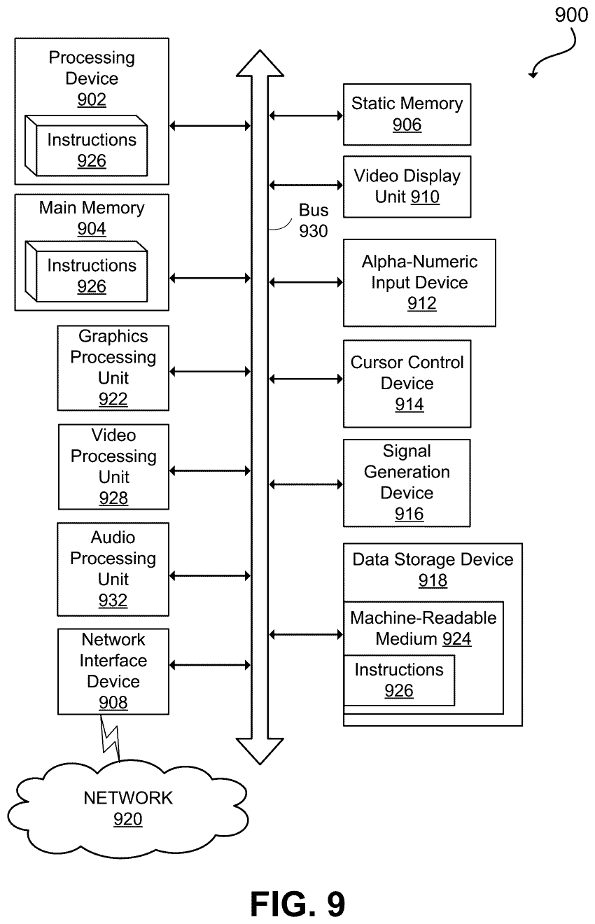

FIG. 8A is a flowchart of a method 800 for manufacturing-aware generation of a metasurface design according to one embodiment of the present disclosure. The method 800 may be implemented by a computer system such as that described below with respect to FIG. 9. At 810, the computer system receives a metasurface design including a plurality of meta-atoms arranged to modify or delay phases of incident waves (e.g., electromagnetic waves, acoustic waves, and the like), the plurality of meta-atoms being selected from a library of different nanoscale nominal meta-atoms. As noted above, the plurality of meta-atoms of the metasurface design are sub-resolution in scale, e.g., each of the meta-atoms is smaller than a wavelength of the incident waves that they affect. At 820, the computer system generates a library of manufacturing-aware meta-atoms based on the library of different nanoscale nominal meta-atoms. At 830, the computer system generates instructions for fabricating an optical metasurface having a layout computed by minimizing a cost function based on the optical metasurface design and the library of manufacturing-aware meta-atoms, as described above with respect to FIG. 6 at 690. In some embodiments of the present disclosure, the cost function is based on overlap maximization (the overlap of shape of the electric field coming out of the metalens (Eout) and the shape of the electric field entering the metalens (Ein) maximized to 100%) and output power (Pout) divided by input power (Pin) maximization to 100% as cost functions to drive metalens optimization. However, embodiments of the present disclosure are not limited thereto and other cost functions may be used, such as based on optimizing absolute focusing efficiency (AFE).

FIG. 8B is a flowchart of a method 850 for generating a library of manufacturing-aware meta-atoms based on simulation according to one embodiment of the present disclosure. As discussed above, in some embodiments, the library of manufacturing-aware meta-atoms is generated by receiving a library of different nominal meta-atoms at 851, then using semiconductor fabrication simulation tools to predict geometry of each meta-atom after manufacturing, including photolithography and etch process stages at 853. In some embodiments, the library of manufacturing-aware meta-atoms is generated in accordance with the embodiments described above, such as simulating the fabrication of the meta-atoms in accordance with photolithographic effects (e.g., low pass filtering in the spatial domain and/or light leakage from adjacent holes) and etching effects (e.g., side-wall angle and surface roughness effects) and/or using microscope images (e.g. scanning electron microscope images) of fabricated nano-scale pillars to generate a library of manufacturing-aware shapes of the meta-atoms, exhibiting various manufacturing-related artifacts. As noted above with respect to FIGS. 7B and 7C, the manufacturing-aware shapes of a given meta-atom may depend on a local context of that meta-atom (the shapes and sizes of neighboring meta-atoms) and therefore, the metasurface design may be used in the process of generating the library of manufacturing-aware meta atoms. The resulting geometries are then associated with the nominal meta-atoms to form the library of manufacturing-aware meta-atoms (e.g., where each of the manufacturing-aware meta-atoms is assigned a name or identifier associated with the corresponding nominal meta-atom of the library of nominal meta-atoms).

FIG. 8C is a flowchart of a method 860 for generating a library of manufacturing-aware meta-atoms based on simulation and parameterization according to one embodiment of the present disclosure. As discussed above, in some embodiments, the library of manufacturing-aware meta-atoms is generated by receiving a library of different nominal meta-atoms at 861, then using semiconductor fabrication simulation tools to predict geometry of each meta-atom after manufacturing, including photolithography and etch process stages at 863. The resulting geometries are then parameterized (e.g., compressed or abstracted to reduce the number of bits used to represent the resulting geometry), such as by converting the simulated geometry into splines, curves, or some other parametric representation. As above, at 865 the resulting parametric representations of the geometries of the fabricated meta-atoms are associated with the nominal meta-atoms to form the library of manufacturing-aware meta-atoms (e.g., where each of the manufacturing-aware meta-atoms is assigned a name or identifier associated with the corresponding nominal meta-atom of the library of nominal meta-atoms).

FIG. 8D is a flowchart of a method 870 for generating a library of manufacturing-aware meta-atoms based on fabrication of meta-atoms and capture of images of the fabricated meta-atoms according to one embodiment of the present disclosure. As discussed above, in some embodiments, the library of manufacturing-aware meta-atoms is generated by receiving a library of different nominal meta-atoms at 871, then physically fabricating one or more of those nominal meta-atoms. At 873, images of the fabricated meta-atoms are captured, such as by using a critical distance scanning electron microscope (CD-SEM). The resulting SEM images can be converted into three-dimensional models representing the geometries of the fabricated meta-atoms. As above, at 875 the resulting captured-image representations of the geometries of the fabricated meta-atoms are associated with the nominal meta-atoms to form the library of manufacturing-aware meta-atoms (e.g., where each of the manufacturing-aware meta-atoms is assigned a name or identifier associated with the corresponding nominal meta-atom of the library of nominal meta-atoms).

Accordingly, aspects of embodiments are directed to optical and manufacturing aware design flow for metasurfaces. Metasurfaces such as a metalens include nano-scale features, such as nano-scale pillars. Adjusting the size (e.g., width or diameter) of the nano-scale pillars affects modifies or delays the phase of incident light (where the nano-scale pillars have dimensions smaller than the wavelength of the light). By placing pillars of different widths on different parts of the metasurface, light incident on different locations of the metasurface is phase shifted or phase delayed by amounts corresponding to the sizes and shapes of the nano-scale pillars at those different locations. However, manufacturing processes can impact the shapes of the fabricated nano-scale pillars. For example, photolithography can apply low-pass filtering in the spatial domain, thereby causing rounding of corners, and reactive ion etching can cause the side-wall angles of the pillars to deviate from exactly perpendicular to the substrate. Design flows according to embodiments of the present disclosure generate a library of manufacturing-aware meta-atoms that account for these manufacturing problems (e.g., that exhibit the artifacts that would be seen in real, fabricated nano-scale pillars). Therefore, simulations of the metasurface design are performed using the manufacturing-aware meta-atoms, such that designers are provided with more accurate simulation results, and thereby shortening the design cycle (e.g., reducing the number of design iterations) because the simulated results using the manufacturing-aware library of meta-atoms more accurately matches the behavior of a fabricated metasurface.

FIG. 9 illustrates an example machine of a computer system 900 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 900 includes a processing device 902, a main memory 904 (e.g., read-only memory (ROM), flash memory, dynamic random-access memory (DRAM) such as synchronous DRAM (SDRAM), etc.), a static memory 906 (e.g., flash memory, static random-access memory (SRAM), etc.), and a data storage device 918, which communicate with each other via a bus 930.

Processing device 902 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 902 may also be one or more special-purpose processing devices such as an application specific integrated circuit (ASIC), a field programmable gate array (FPGA), a digital signal processor (DSP), network processor, or the like. The processing device 902 may be configured to execute instructions 926 for performing the operations and steps described herein.

The computer system 900 may further include a network interface device 908 to communicate over the network 920. The computer system 900 also may include a video display unit 910 (e.g., a liquid crystal display (LCD) or a cathode ray tube (CRT)), an alphanumeric input device 912 (e.g., a keyboard), a cursor control device 914 (e.g., a mouse), a signal generation device 916 (e.g., a speaker), graphics processing unit 922, video processing unit 928, and audio processing unit 932.

The data storage device 918 may include a machine-readable storage medium 924 (also known as a non-transitory computer-readable medium) on which is stored one or more sets of instructions 926 or software embodying any one or more of the methodologies or functions described herein. The instructions 926 may also reside, completely or at least partially, within the main memory 904 and/or within the processing device 902 during execution thereof by the computer system 900, the main memory 904 and the processing device 902 also constituting machine-readable storage media.

In some implementations, the instructions 926 include instructions to implement functionality corresponding to the present disclosure. While the machine-readable storage medium 924 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 902 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer-readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

It should be understood that the sequence of steps of the processes described herein in regard to various methods and with respect various flowcharts is not fixed, but can be modified, changed in order, performed differently, performed sequentially, concurrently, or simultaneously, or altered into any desired order consistent with dependencies between steps of the processes, as recognized by a person of skill in the art. Further, as used herein and in the claims, the phrase “at least one of element A, element B, or element C” is intended to convey any of: element A, element B, element C, elements A and B, elements A and C, elements B and C, and elements A, B, and C.

According to one embodiment of the present disclosure, a method includes: receiving a metasurface design including a plurality of meta-atoms arranged to modify phases of incident waves, the plurality of meta-atoms being from a library of different nominal meta-atoms; generating, by a processing device, a library of manufacturing-aware meta-atoms based on the library of different nominal meta-atoms; and generating instructions for fabricating a manufacturing-aware metasurface having layout computed using a cost function based on the metasurface design and the library of manufacturing-aware meta-atoms.

The library of manufacturing-aware meta-atoms may include a plurality of manufacturing-aware meta-atoms, each corresponding to a shape of an isolated, fabricated meta-atom of the library of different nominal meta-atoms.

The library of manufacturing-aware meta-atoms may include a plurality of manufacturing-aware meta-atoms, each corresponding to a shape of a fabricated meta-atom of the library of different nominal meta-atoms in a local context of fabricating one or more adjacent neighboring meta-atoms.

The library of manufacturing-aware meta-atoms may include a plurality of manufacturing-aware meta-atoms, each corresponding to a shape of a fabricated one of the library of different nominal meta-atoms in a full context of fabricating meta-atoms of the metasurface design.

The library of manufacturing-aware meta-atoms may include a plurality of parameterized curves, each corresponding to a parameterized shape of an isolated, fabricated meta-atom of the library of different nominal meta-atoms.

The library of manufacturing-aware meta-atoms may include a plurality of scanning electron microscopy (SEM) images, each corresponding to an SEM image of a fabricated meta-atom of the library of different nominal meta-atoms.

The library of manufacturing-aware meta-atoms may represent the shapes of the meta-atoms of the library of different nominal meta-atoms the meta-atoms are fabricated using a microfabrication process.

A manufacturing-aware meta-atom may have a side wall angle that is oblique with respect to a substrate, and the manufacturing-aware meta-atom may have a shape that is low-pass filtered in a spatial domain with respect to a corresponding one of the library of different nominal meta-atoms.

The metasurface design may include an optical metasurface design, wherein the incident waves include electromagnetic waves.

The metasurface design may include an acoustic metasurface design, wherein the incident waves include acoustic waves.

According to one embodiment of the present disclosure, a system includes: a memory storing instructions; and a processor, coupled with the memory and to execute the instructions, the instructions when executed cause the processor to: receive a metasurface design including a plurality of meta-atoms arranged to apply phase delay to incident waves, the plurality of meta-atoms being from a library of different nominal meta-atoms; generate a library of manufacturing-aware meta-atoms based on the library of different nominal meta-atoms based on predictions of manufacturing artifacts from fabricating the nominal meta-atoms; and generate instructions for fabricating a metasurface having a layout computed using a cost function based on the metasurface design and the library of manufacturing-aware meta-atoms.

The manufacturing artifacts may include side-wall angle artifacts.

The manufacturing artifacts may include corner rounding artifacts.

The predictions of the manufacturing artifacts may be computed by a fabrication process simulator.

According to one embodiment of the present disclosure, a non-transitory computer-readable medium including stored instructions, which when executed by a processor, cause the processor to: receive a metasurface design including a plurality of meta-atoms arranged to modify phases of incident waves, the plurality of meta-atoms being from a library of different nominal meta-atoms; generate a library of manufacturing-aware meta-atoms based on the library of different nominal meta-atoms; and generate instructions for fabricating a manufacturing-aware metasurface having layout computed using a cost function based on the metasurface design and the library of manufacturing-aware meta-atoms.

The library of manufacturing-aware meta-atoms may include a plurality of manufacturing-aware meta-atoms, each corresponding to a shape of an isolated, fabricated meta-atom of the library of different nominal meta-atoms.

The library of manufacturing-aware meta-atoms may include a plurality of manufacturing-aware meta-atoms, each corresponding to a shape of a fabricated meta-atom of the library of different nominal meta-atoms in a local context of fabricating one or more adjacent neighboring meta-atoms or a full context of fabricating meta-atoms of the metasurface design.

The library of manufacturing-aware meta-atoms may include a plurality of parameterized curves, each corresponding to a parameterized shape of an isolated, fabricated meta-atom of the library of different nominal meta-atoms.

The library of manufacturing-aware meta-atoms may represent the shapes of the meta-atoms of the library of different nominal meta-atoms the meta-atoms are fabricated using a microfabrication process, wherein a manufacturing-aware meta-atom may have a side wall angle that is oblique with respect to a substrate, and wherein the manufacturing-aware meta-atom may have a shape that is low-pass filtered in a spatial domain with respect to a corresponding one of the library of different nominal meta-atoms.

The metasurface design may include an optical metasurface design, wherein the incident waves may include electromagnetic waves.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method comprising:
receiving a metasurface design comprising a plurality of meta-atoms arranged to modify phases of incident waves, the plurality of meta-atoms being from a library of different nominal meta-atoms;
generating, by a processing device, a library of manufacturing-aware meta-atoms based on the library of different nominal meta-atoms; and
generating instructions for fabricating a manufacturing-aware metasurface having layout computed using a cost function based on the metasurface design and the library of manufacturing-aware meta-atoms.

2. The method of claim 1, wherein the library of manufacturing-aware meta-atoms comprises a plurality of manufacturing-aware meta-atoms, each corresponding to a shape of an isolated, fabricated meta-atom of the library of different nominal meta-atoms.

3. The method of claim 1, wherein the library of manufacturing-aware meta-atoms comprises a plurality of manufacturing-aware meta-atoms, each corresponding to a shape of a fabricated meta-atom of the library of different nominal meta-atoms in a local context of fabricating one or more adjacent neighboring meta-atoms.

4. The method of claim 1, wherein the library of manufacturing-aware meta-atoms comprises a plurality of manufacturing-aware meta-atoms, each corresponding to a shape of a fabricated one of the library of different nominal meta-atoms in a full context of fabricating meta-atoms of the metasurface design.

5. The method of claim 1, wherein the library of manufacturing-aware meta-atoms comprises a plurality of parameterized curves, each corresponding to a parameterized shape of an isolated, fabricated meta-atom of the library of different nominal meta-atoms.

6. The method of claim 1, wherein the library of manufacturing-aware meta-atoms comprises a plurality of scanning electron microscopy (SEM) images, each corresponding to an SEM image of a fabricated meta-atom of the library of different nominal meta-atoms.

7. The method of claim 1, wherein the library of manufacturing-aware meta-atoms represents the shapes of the meta-atoms of the library of different nominal meta-atoms the meta-atoms are fabricated using a microfabrication process.

8. The method of claim 7,
wherein a manufacturing-aware meta-atom has a side wall angle that is oblique with respect to a substrate, and
wherein the manufacturing-aware meta-atom has a shape that is low-pass filtered in a spatial domain with respect to a corresponding one of the library of different nominal meta-atoms.

9. The method of claim 1, wherein the metasurface design comprises an optical metasurface design, wherein the incident waves comprise electromagnetic waves.

10. The method of claim 1, wherein the metasurface design comprises an acoustic metasurface design, wherein the incident waves comprise acoustic waves.

11. A system comprising:
a memory storing instructions; and
a processor, coupled with the memory and to execute the instructions, the instructions when executed cause the processor to:
receive a metasurface design comprising a plurality of meta-atoms arranged to apply phase delay to incident waves, the plurality of meta-atoms being from a library of different nominal meta-atoms;
generate a library of manufacturing-aware meta-atoms based on the library of different nominal meta-atoms based on predictions of manufacturing artifacts from fabricating the nominal meta-atoms; and
generate instructions for fabricating a metasurface having a layout computed using a cost function based on the metasurface design and the library of manufacturing-aware meta-atoms.

12. The system of claim 11, wherein the manufacturing artifacts comprise side-wall angle artifacts.

13. The system of claim 11, wherein the manufacturing artifacts comprise corner rounding artifacts.

14. The system of claim 11, wherein the predictions of the manufacturing artifacts are computed by a fabrication process simulator.

15. A non-transitory computer-readable medium comprising stored instructions, which when executed by a processor, cause the processor to:
receive a metasurface design comprising a plurality of meta-atoms arranged to modify phases of incident waves, the plurality of meta-atoms being from a library of different nominal meta-atoms;
generate a library of manufacturing-aware meta-atoms based on the library of different nominal meta-atoms; and
generate instructions for fabricating a manufacturing-aware metasurface having layout computed using a cost function based on the metasurface design and the library of manufacturing-aware meta-atoms.

16. The non-transitory computer-readable medium of claim 15, wherein the library of manufacturing-aware meta-atoms comprises a plurality of manufacturing-aware meta-atoms, each corresponding to a shape of an isolated, fabricated meta-atom of the library of different nominal meta-atoms.

17. The non-transitory computer-readable medium of claim 15, wherein the library of manufacturing-aware meta-atoms comprises a plurality of manufacturing-aware meta-atoms, each corresponding to a shape of a fabricated meta-atom of the library of different nominal meta-atoms in a local context of fabricating one or more adjacent neighboring meta-atoms or a full context of fabricating meta-atoms of the metasurface design.

18. The non-transitory computer-readable medium of claim 15, wherein the library of manufacturing-aware meta-atoms comprises a plurality of parameterized curves, each corresponding to a parameterized shape of an isolated, fabricated meta-atom of the library of different nominal meta-atoms.

19. The non-transitory computer-readable medium of claim 15, wherein the library of manufacturing-aware meta-atoms represents the shapes of the meta-atoms of the library of different nominal meta-atoms the meta-atoms are fabricated using a microfabrication process,
wherein a manufacturing-aware meta-atom has a side wall angle that is oblique with respect to a substrate, and
wherein the manufacturing-aware meta-atom has a shape that is low-pass filtered in a spatial domain with respect to a corresponding one of the library of different nominal meta-atoms.

20. The non-transitory computer-readable medium of claim 15, wherein the metasurface design comprises an optical metasurface design, wherein the incident waves comprise electromagnetic waves.
